(19) United States
(12) Patent Application Publication
(10) Pub. No.: US 2006/0269778 A1
(43) Pub. Date: Nov. 30, 2006

(54) Electroluminescent materials and devices

(75) Inventors: Poopathy Kathirgamanathan, North Harrow (GB); Richard Price, London (GB); Subramaniam Ganeshamurugan, London (GB); Gnanamoly Paramaswara, London (GB)

Correspondence Address: David Silverstein;Andover IP Law, Suite 300, 44 Park Street, Andover, MA, 01810, US

(73) Assignee: ELAM-T LIMITED, Innova Park (GB)

(21) Appl. No.: 10/540,732

(22) PCT Filed: Dec. 23, 2003
(86) PCT No.: PCT/GB03/05660

§ 371 Date: Jul. 25, 2005

(30) Foreign Application Priority Data
Dec. 24, 2002 (GB) 0230076.2

(51) Int. Cl. H01L 51/54; H05B 33/14; C09K 11/06

(52) U.S. Cl. 428/690; 428/917; 313/504; 313/506; 257/E51.044; 546/4

(57) ABSTRACT

An electroluminescent compound is an organic diiridium acatylacetonate complex.

The present invention relates to electroluminescent materials and to electroluminescent devices.

Materials which emit light when an electric current is passed through them are well known and used in a wide range of display applications. Liquid crystal devices and devices which are based on inorganic semiconductor systems are widely used; however these suffer from the disadvantages of high energy consumption, high cost of manufacture, low quanta efficiency and the inability to make flat panel displays.

Organic polymers have been proposed as useful in electroluminescent devices, but it is not possible to obtain pure colours; they are expensive to make and have a relatively low efficiency.

Another compound which has been proposed is aluminium quinolate, but this requires dopants to be used to obtain a range of colours and has a relatively low efficiency.

Patent application WO98/58037 describes a range of lanthanide complexes which can be used in electroluminescent devices which have improved properties and give better results. Patent Applications PCT/GB98/01773, PCT/GB99/03619, PCT/GB99/04030, PCT/GB99/04024, PCT/GB99/04028, PCT/GB00/00268 describe electroluminescent complexes, structures and devices using rare earth chelates.

U.S. Pat. No. 5,128,587 discloses an electroluminescent device which consists of an organometallic complex of rare earth elements of the lanthanide series sandwiched between a transparent electrode of high work function and a second electrode of low work function with a hole conducting layer interposed between the electroluminescent layer and the transparent high work function electrode and an electron conducting layer interposed between the electroluminescent layer and the electron injecting low work function anode. The hole conducting layer and the electron conducting layer are required to improve the working and the efficiency of the device. The hole transporting layer serves to transport holes and to block the electrons, thus preventing electrons from moving into the electrode without recombining with holes. The recombination of carriers therefore mainly takes place in the emitter layer.

We have now devised electroluminescent compounds and electroluminescent structures incorporating them.

According to the invention there is provided an electroluminescent diiridium compound of formula 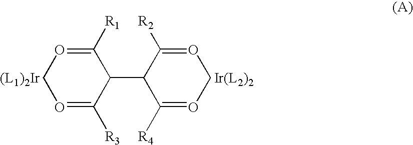
where R₁, R₂, R₃ and R₄ can be the same or different and are selected from hydrogen, and substituted and unsubstituted hydrocarbyl groups such as substituted and unsubstituted aliphatic groups, substituted and unsubstituted aromatic, heterocyclic and polycyclic ring structures, fluorocarbons such as trifluoryl methyl groups, halogens such as fluorine or thiophenyl groups; R₁, R₂ and R₃ can also form substituted and unsubstituted fused aromatic, heterocyclic and polycyclic ring structures and can be copolymerisable with a monomer, e.g. styrene.

Examples of R₁ and/or R₂ and/or R₃ and/or R₄ include aliphatic, aromatic and heterocyclic alkoxy, aryloxy and carboxy groups, substituted and unsubstituted phenyl, fluorophenyl, biphenyl, phenanthrene, anthracene, naphthyl and fluorene groups, alkyl groups such as t-butyl, heterocyclic groups such as carbazole.

Preferred organic ligands L₁ and L₂ are phenylpyridine and substituted phenylpryidines.

The invention also provides an electroluminescent device which comprises (i) a first electrode, (ii) a layer of the diiridium complex (A) and (iii) a second electrode.

The first electrode can function as the cathode and the second electrode can function as the anode and preferably there is a layer of a hole transporting material between the anode and the layer of the electroluminescent compound.

The hole transporting material can be any of the hole transporting materials used in electroluminescent devices.

The hole transporting material can be an amine complex such as poly (vinylcarbazole), N,N′-diphenyl-N,N′-bis(3-methylphenyl)-1,1′-biphenyl-4,4′-diamine (TPD), an unsubstituted or substituted polymer of an amino substituted aromatic compound, a polyaniline, substituted polyanilines, polythiophenes, substituted polythiophenes, polysilanes etc. Examples of polyanilines are polymers of

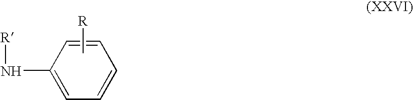

where R is in the ortho—or meta-position and is hydrogen, C1-18 alkyl, C1-6 alkoxy, amino, chloro, bromo, hydroxy or the group

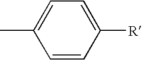

where R is alky or aryl and R′ is hydrogen, C1-6 alkyl or aryl with at least one other monomer of formula I above, or the hole transporting material can be a polyaniline; polyanilines which can be used in the present invention have the general formula

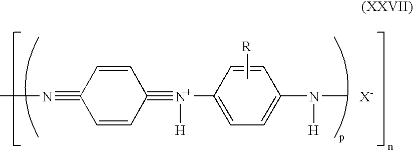

where p is from 1 to 10 and n is from 1 to 20, R is as defined above and X is an anion, preferably selected from Cl, Br, SO₄, BP₄, PF₆, H₂PO₃, H₂PO₄, arylsulphonate, arenedicarboxylate, polystyrenesulphonate, polyacrylate alkysulphonate, vinylsulphonate, vinylbenzene sulphonate, cellulose sulphonate, camphor sulphonates, cellulose sulphate or a perfluorinated polyanion.

Examples of arylsulphonates are p-toluenesulphonate, benzenesulphonate, 9,10-anthraquinone-sulphonate and anthracenesulphonate; an example of an arenedicarboxylate is phthalate and an example of arenecarboxylate is benzoate.

We have found that protonated polymers of the unsubstituted or substituted polymer of an amino substituted aromatic compound such as a polyaniline are difficult to evaporate or cannot be evaporated. However we have surprisingly found that if the unsubstituted or substituted polymer of an amino substituted aromatic compound is deprotonated then it can be easily evaporated, i.e. the polymer is evaporable.

Preferably evaporable deprotonated polymers of unsubstituted or substituted polymers of an amino substituted aromatic compound are used. The de-protonated unsubstituted or substituted polymer of an amino substituted aromatic compound can be formed by deprotonating the polymer by treatment with an alkali such as ammonium hydroxide or an alkali metal hydroxide such as sodium hydroxide or potassium hydroxide.

The degree of protonation can be controlled by forming a protonated polyaniline and de-protonating. Methods of preparing polyanilines are described in the article by A. G. MacDiarmid and A. F. Epstein, Faraday Discussions, Chem Soc. 88 P319 1989.

The conductivity of the polyaniline is dependent on the degree of protonation with the maximum conductivity being when the degree of protonation is between 40 and 60%, e.g. about 50%.

Preferably the polymer is substantially fully deprotonated.

A polyaniline can be formed of octamer units, i.e. p is four, e.g.

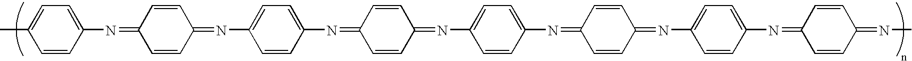

The polyanilines can have conductivities of the order of 1×10⁻¹ Siemen cm⁻¹ or higher.

The aromatic rings can be unsubstituted or substituted, e.g. by a C1 to 20 alkyl group such as ethyl.

The polyaniline can be a copolymer of aniline and preferred copolymers are the copolymers of aniline with o-anisidine, m-sulphanilic acid or o-aminophenol, or o-toluidine with o-aminophenol, o-ethylaniline, o-phenylene diamine or with amino anthracenes.

Other polymers of an amino substituted aromatic compound which can be used include substituted or unsubstituted polyaminonapthalenes, polyaminoanthracenes, polyaminophenanthrenes, etc. and polymers of any other condensed polyaromatic compound. Polyaminoanthracenes and methods of making them are disclosed in U.S. Pat. No. 6,153,726. The aromatic rings can be unsubstituted or substituted, e.g. by a group R as defined above.

Other hole transporting materials are conjugated polymers and the conjugated polymers which can be used can be any of the conjugated polymers disclosed or referred to in U.S. Pat. No. 5,807,627, PCT/WO90/13148 and PCT/WO92/03490.

The preferred conjugated polymers are poly (p-phenylenevinylene)-PPV and copolymers including PPV. Other preferred polymers are poly(2,5 dialkoxyphenylene vinylene) such as poly (2-methoxy-5-(2-methoxypentyloxy-1,4-phenylene vinylene), poly(2-methoxypentyloxy)-1,4-phenylenevinylene), poly(2-methoxy-5-(2-dodecyloxy-1,4-phenylenevinylene) and other poly(2,5 dialkoxyphenylenevinylenes) with at least one of the alkoxy groups being a long chain solubilising alkoxy group, poly fluorenes and oligofluorenes, polyphenylenes and oligophenylenes, polyanthracenes and oligo anthracenes, polythiophenes and oligothiophenes.

In PPV the phenylene ring may optionally carry one or more substituents, e.g. each independently selected from alkyl, preferably methyl, alkoxy, preferably methoxy or ethoxy.

Any poly(arylenevinylene) including substituted derivatives thereof can be used and the phenylene ring in poly(p-phenylenevinylene) may be replaced by a fused ring system such as anthracene or naphthylene ring and the number of vinylene groups in each polyphenylenevinylene moiety can be increased, e.g. up to 7 or higher.

The conjugated polymers can be made by the methods disclosed in U.S. Pat. No. 5,807,627, PCT/WO90/13148 and PCT/WO92/03490.

The thickness of the hole transporting layer is preferably 20 nm to 200 nm.

The polymers of an amino substituted aromatic compound such as polyanilines referred to above can also be used as buffer layers with or in conjunction with other hole transporting materials.

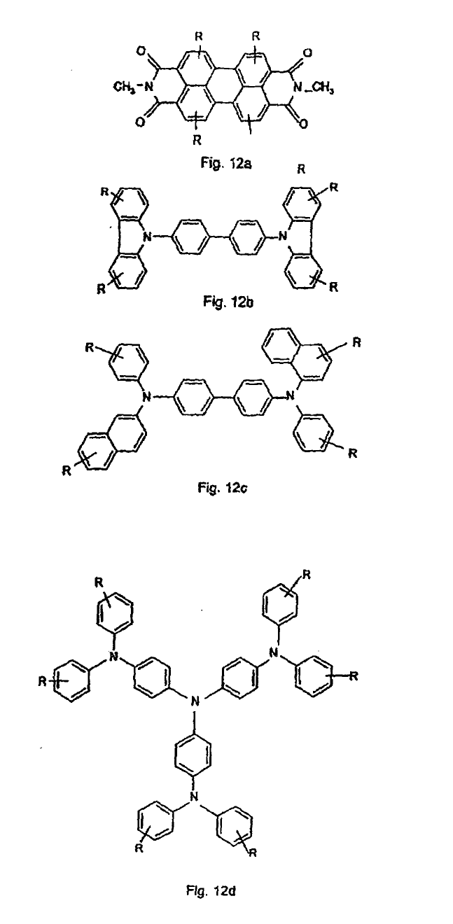

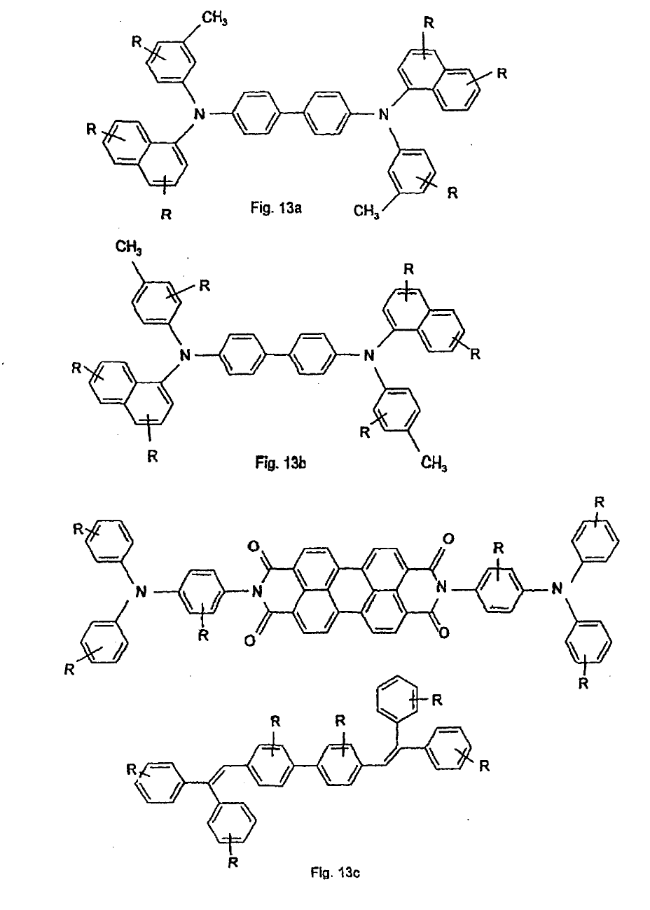

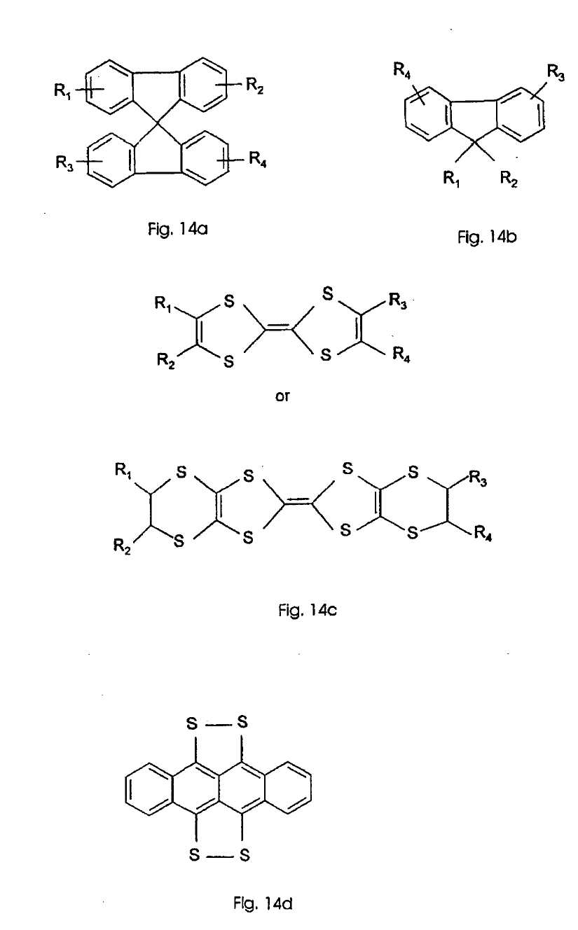

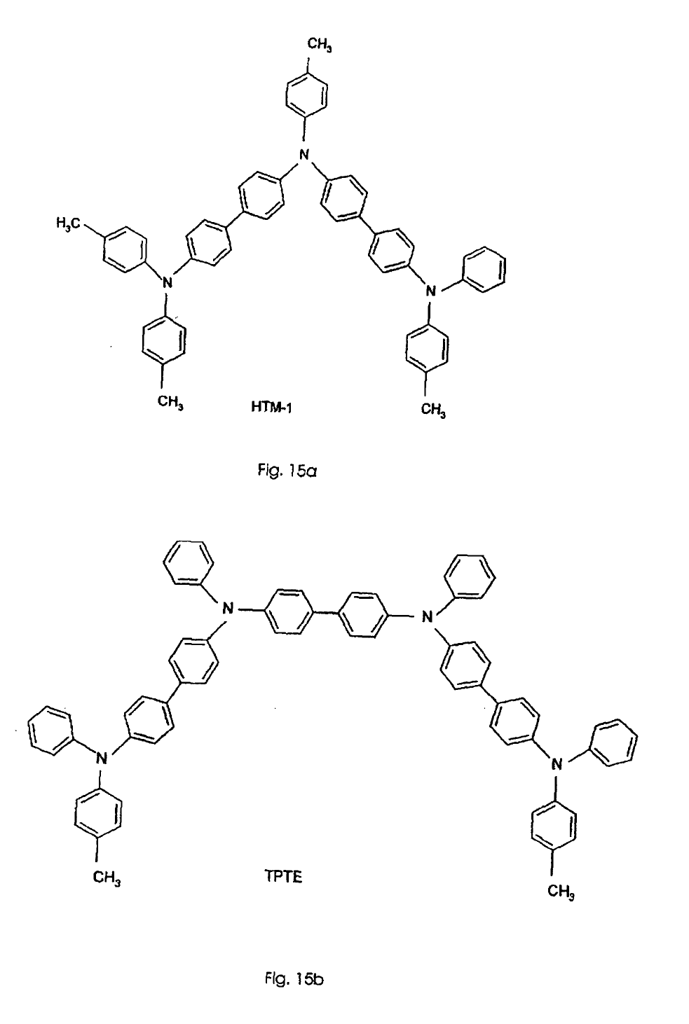

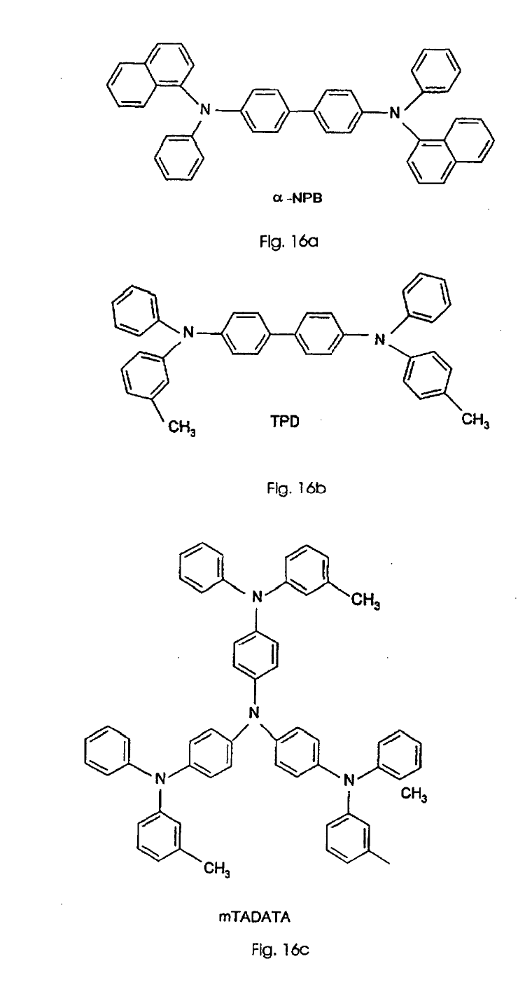

The structural formulae of some other hole transporting materials are shown in FIGS. 12 to 16 of the drawings, where R₁, R₂ and R₃ can be the same or different and are selected from hydrogen, and substituted and unsubstituted hydrocarbyl groups such as substituted and unsubstituted aliphatic groups, substituted and unsubstituted aromatic, heterocyclic and polycyclic ring structures, fluorocarbons such as trifluoryl methyl groups, halogens such as fluorine or thiophenyl groups; R₁, R₂ and R₃ can also form substituted and unsubstituted fused aromatic, heterocyclic and polycyclic ring structures and can be copolymerisable with a monomer, e.g. style. X is Se, S or O, Y can be hydrogen, substituted or unsubstituted hydrocarbyl groups, such as substituted and unsubstituted aromatic, heterocyclic and polycyclic ring structures, fluorine, fluorocarbons such as trifluoryl methyl groups, halogens such as fluorine or thiophenyl groups or nitrile.

Examples of R₁ and/or R₂ and/or R₃ include aliphatic, aromatic and heterocyclic alkoxy, aryloxy and carboxy groups, substituted and substituted phenyl, fluorophenyl, biphenyl, phenanthrene, anthracene, naphthyl and fluorene groups alkyl groups such as t-butyl, heterocyclic groups such as carbazole.

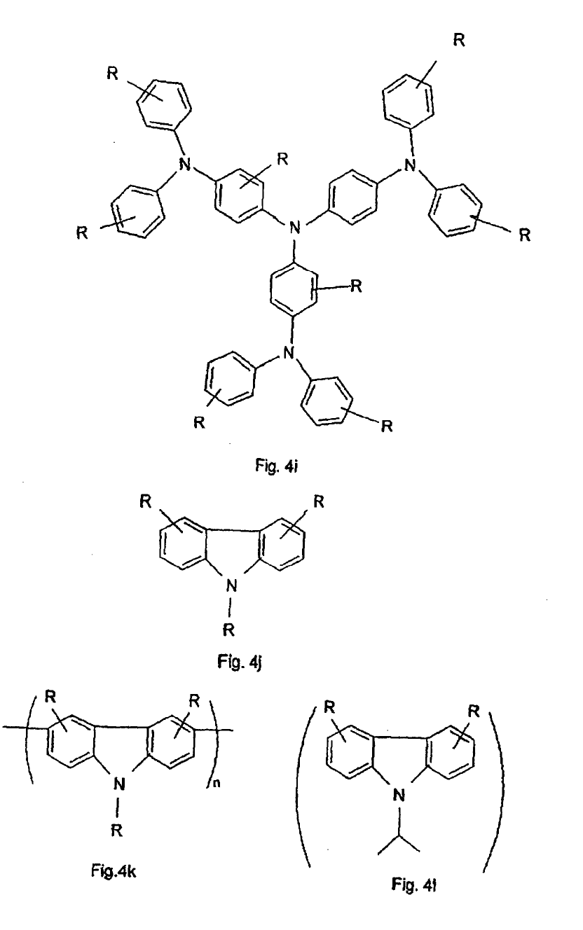

In an embodiment of the invention the hole transporting material is mixed with the electroluminescent compound in the electroluminescent layer and a preferred electroluminescent compound is CBP which has the formula of FIG. 4b in the drawings.

There can be a buffer layer between the anode and the hole sporting layer and any of the hole transporting materials listed above can be used.

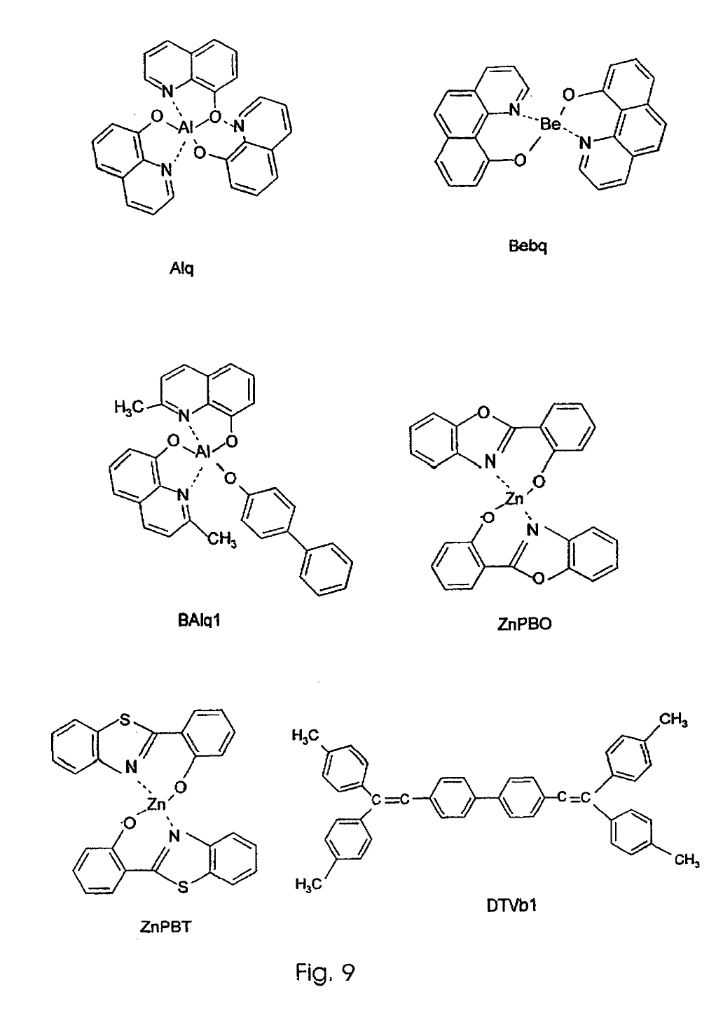

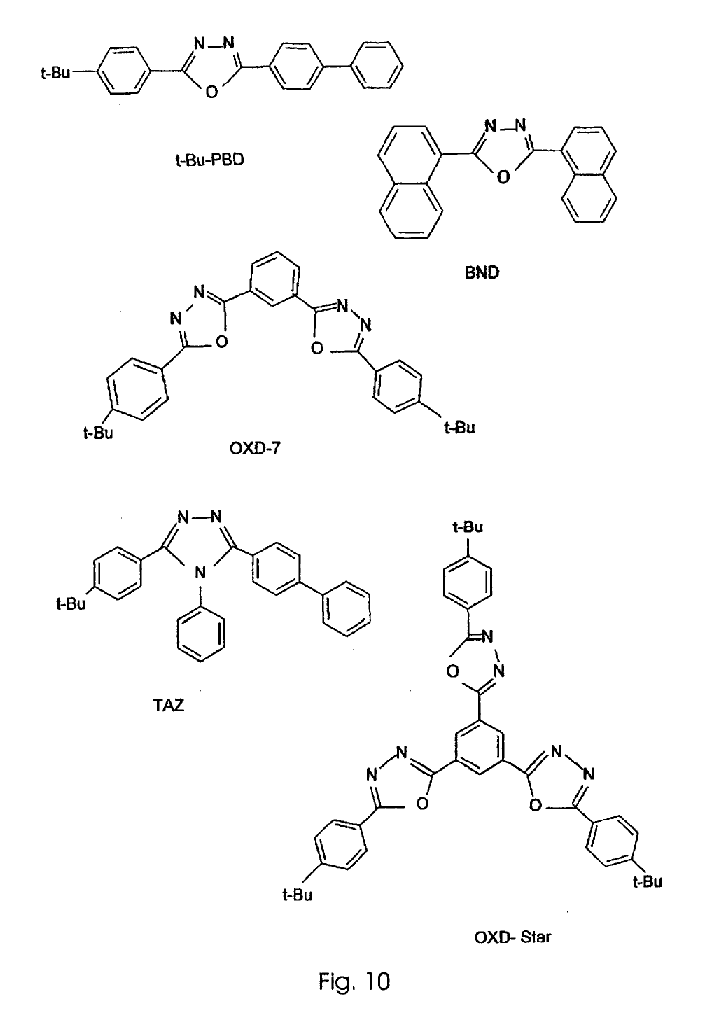

Optionally there is a layer of an electron injecting material between the cathode and the electroluminescent material layer. The electron injecting material is a material which will transport electrons; when an electric current is passed through electron injecting materials include a metal complex such as a metal quinolate, e.g. an aluminium quinolate, lithium quinolate, Mx(DBM)ₙ where Mx is a metal and DBM is dibenzoyl methane and n is the valency of Mx, e.g Mx is chromium. The electron injecting material can also be a cyano anthracene such as 9,10 dicyano anthracene, cyano substituted aromatic compounds, tetracyanoquinidodimethane a polystyrene sulphonate or a compound with the structural formulae shown in FIGS. 9 or 10 of the drawings in which the phenyl rings can be substituted with substituents R as defined above. Instead of being a separate layer the electron injecting material can be mixed with the electroluminescent material and co-deposited with it.

Optionally the hole transporting material can be mixed wit the electroluminescent material and co-deposited with it.

The hole transporting materials, the electroluminescent material and the electron injecting materials can be mixed together to form one layer, which simplifies the construction.

The anode is preferably a transparent substrate such as a conductive glass or plastic material which acts as the anode. Preferred substrates are conductive glasses such as indium tin oxide coated glass, but any glass which is conductive or has a conductive layer such as a metal or conductive polymer can be used. Conductive polymers and conductive polymer coated glass or plastics materials can also be used as the substrate.

The cathode is preferably a low work function metal, e.g. aluminiuni, calcium, lithium, magnesium and alloys thereof such as silver/magnesium alloys, rare earth metal alloys, etc; aluminium is a preferred metal. A metal fluoride such as an alkali metal, rare earth metal or their alloys can be used as the second electrode, for example by having a metal fluoride layer formed on a metal.

The diiridium compound (A) can be mixed with other electroluminescent compounds, for example europium complexes and the invention also provides an electroluminescent device which comprises (i) a first electrode, (ii) a layer of an electroluminescent europium organo metallic or organic complex mixed with an iridium organo metallic or organic complex and (iii) a second electrode.

There is preferably also a layer of an electroluminescent europium organo metallic or organic complex and the invention also provides electroluminescent devices of structures: (i) a first electrode, (ii) a layer of an electroluminescent europium organo metallic or organic complex, (iii) a layer of an electroluminescent europium organo metallic or organic complex mixed with diiridium compound and (iv) a second electrode.

The electroluminescent europium organo metallic or organic complex preferably has the formula (Lα)₃Eu where Lα is an organic complex.

Preferred electroluminescent compounds which can be used in the present invention are of formula
(Lα)₃ Eu←Lp
where Lα and Lp are organic ligands and Lp is a neutral ligand. The ligands Lα can be the same or different and there can be a plurality of ligands Lp which can be the same or different.

For example (L₁)(L₂)(L₃)Eu (Lp) where (L₁)(L₂)(L₃) are the same or different organic complexes and (Lp) is a neutral ligand and the different groups (L₁)(L₂)(L₃) may be the same or different.

Lp can be monodentate, bidentate or polydentate and there can be one or more ligands Lp.

Further electroluminescent compounds which can be used in the present invention are of general formula (Lα)ₙEuM₂ where M₂ is a non rare earth metal, Lα is a as above and n is the combined valence state of Eu and M₂. The complex can also comprise one or more neutral ligands Lp so the complex has the general formula (Lα)ₙ Eu M₂ (Lp), where Lp is as above. The metal M₂ can be any metal which is not a rare earth, transition metal, lanthanide or an actinide. Examples of metals which can be used include lithium, sodium, potassium, rubidium, caesium, beryllium, magnesium, calcium, strontium, barium, copper (I), copper (II), silver, gold, zinc, cadmium, boron, aluminium, gallium, indium, germanium, tin (II), tin (IV), antimony (II), antimony (IV), lead (II), lead (IV) and metals of the first, second and third groups of transition metals in different valence states, e.g. manganese, iron, ruthenium, osmium, cobalt, nickel, palladium(II), palladium(IV), platinum(II), platinum(IV), cadmium, chromium. titanium, vanadium, zirconium, tantulum, molybdenum, rhodium, iridium, titanium, niobium, scandium, yttrium.

Preferably Lα is selected from β diketones such as those of formulae 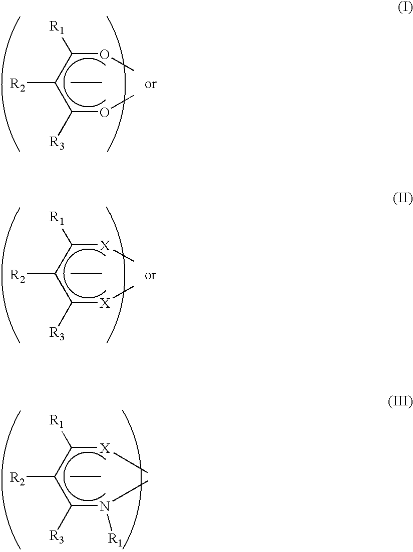
where R₁, R₂ and R₃ can be the same or different and are selected from hydrogen, and substituted and unsubstituted hydrocarbyl groups such as substituted and unsubstituted aliphatic groups, substituted and unsubstituted aromatic, heterocyclic and polycyclic ring structures, fluorocarbons such as trifluoryl methyl groups, halogens such as fluorine or thiophenyl groups. R₁, R₂ and R₃ can also form substituted and unsubstituted fused aromatic, heterocyclic and polycyclic ring structures and can be copolymerisable with a monomer, e.g. styrene. X is Se, S or O, Y can be hydrogen, substituted or unsubstituted hydrocarbyl groups, such as substituted and unsubstituted aromatic, heterocyclic and polycyclic ring structures, fluorine, fluorocarbons such as trifluoryl methyl groups, halogens such as fluorine or thiophenyl groups or nitrile.

Examples of R₁ and/or R₂ and/or R₃ include aliphatic, aromatic and heterocyclic alkoxy, aryloxy and carboxy groups, substituted and substituted phenyl, fluorophenyl, biphenyl, phenanthrene, anthracene, naphthyl and fluorene groups alkyl groups such as t-butyl, heterocyclic groups such as carbazole.

Some of the different groups Lα may also be the same or different charged groups such as carboxylate groups so that the group L₁ can be as defined above and the groups L₂, L₃ . . . can be charged groups such as 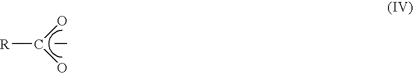
where R is R₁ as defined above or the groups L₁, L₂ can be as defined above and L₃ . . . etc. are other charged groups

R₁, R₂ and R₃ can also be 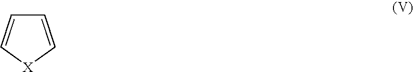
where X is O, S, Se or NH.

A preferred moiety R₁ is trifluoromethyl CF₃ and examples of such diketones are, banzoyltrifluoroacetone, p-chlorobenzoyltrifluoroacetone, p-bromotrifluoroacetone, p-phenyltrifluoroacetone, 1-naphthoyltrifluoroacetone, 2-naphthoyltrifluoroacetone, 2-phenathoyltrifluoroacetone, 3-phenanthoyltrifluoroacetone, 9-anthroyltrifluoroacetonetrifluoroacetone, cinnamoyltrifluoroacetone, and 2-thenoyltrifluoroacetone.

The different groups Lα may be the same or different ligands of formulae 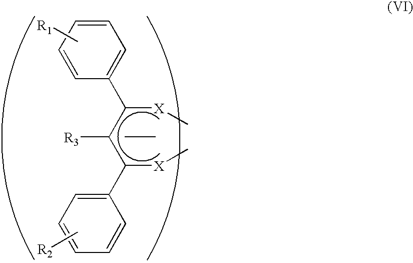
where X is O, S, or Se and R₁ R₂ and R₃ are as above.

The different groups Lα may be the same or different quinolate derivatives such as 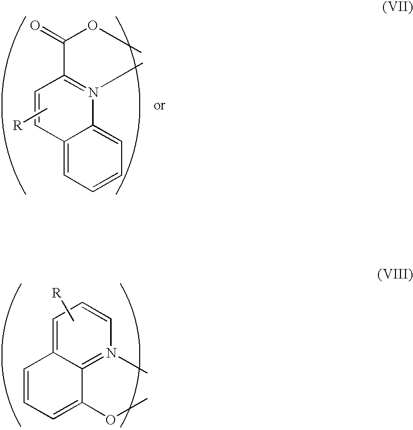
where R is hydrocarbyl, aliphatic, aromatic or heterocyclic carboxy, aryloxy, hydroxy or alkoxy, e.g. the 8 hydroxy quinolate derivatives or 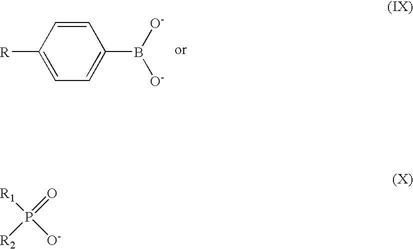
where R, R₁, and R₂ are as above or are H or F e.g. R₁ and R₂ are alkyl or alkoxy groups

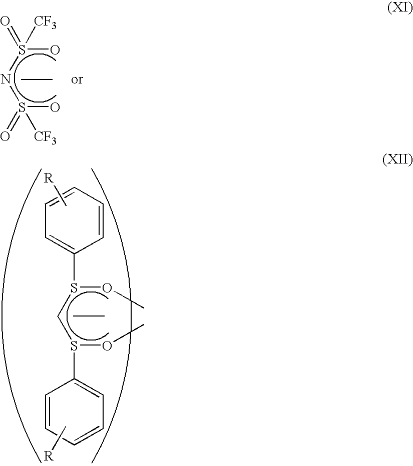

As stated above, the different groups Lα may also be the same or different carboxylate groups, e.g. 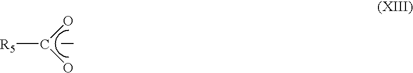
where R₅ is a substituted or unsubstituted aromatic, polycyclic or heterocyclic ring a polypyridyl group, R₅ can also be a 2-ethyl hexyl group so Lₙ is 2-ethylhexanoate or R₅ can be a chair structure so that Lₙ is 2-acetyl cyclohexanoate or Lα can be 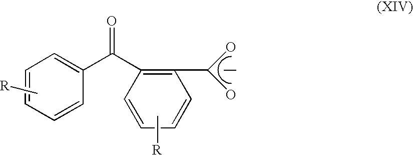
where R is as above, e.g. alkyl, allenyl, amino or a fused ring such as a cyclic or polycyclic ring.

The different groups Lα may also be 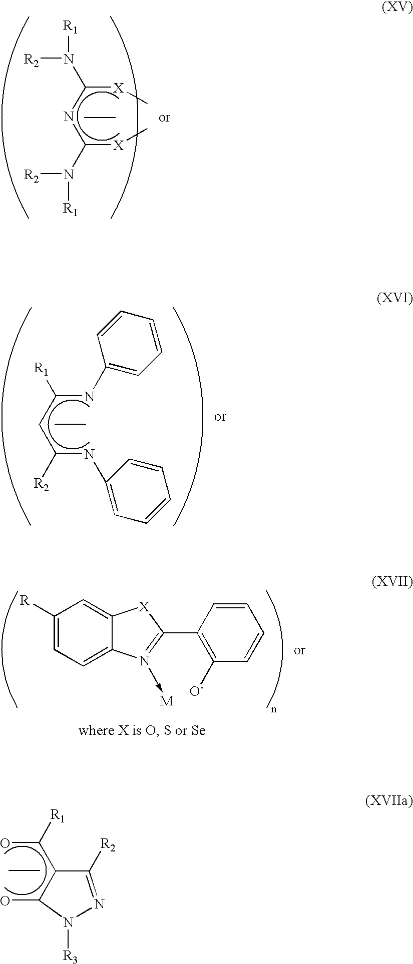
where R, R₁ and R₂ are as above or

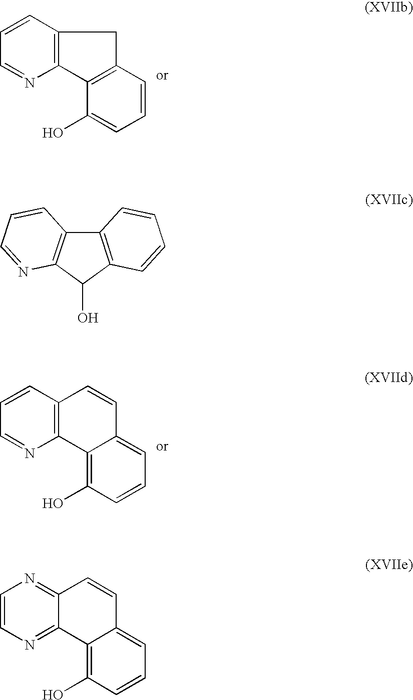

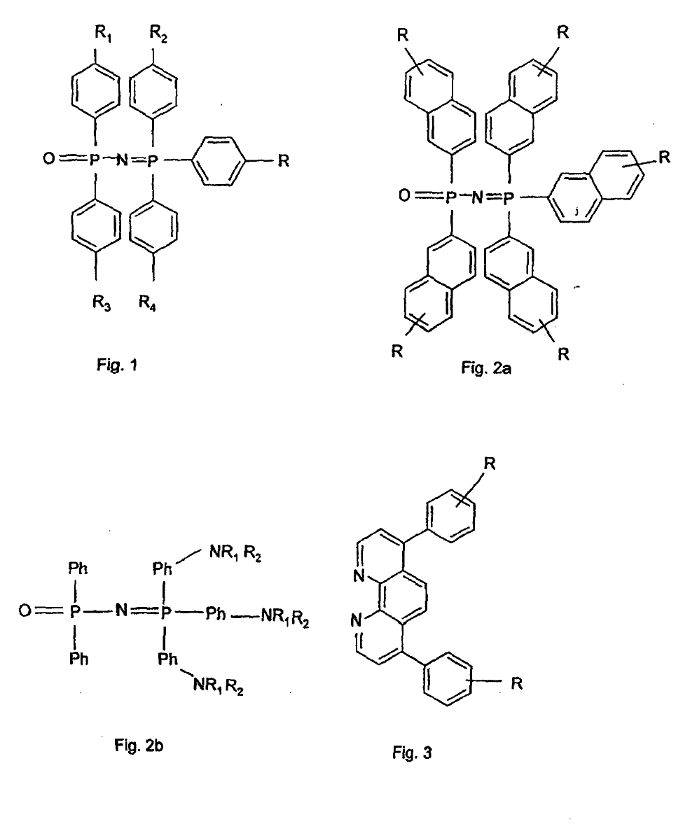

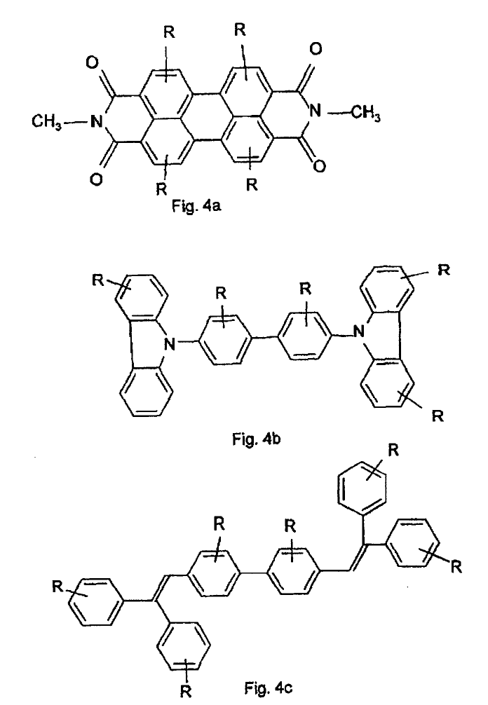

The groups Lₚ in the formula (A) above can be selected from 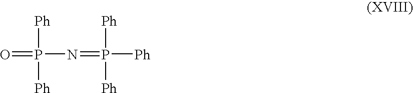
where each Ph which can be the same or different and can be a phenyl (OPNP) or a substituted phenyl group, other substituted or unsubstituted aromatic group, a substituted or unsubstituted heterocyclic or polycyclic group, a substituted or unsubstituted fused aromatic group such as a naphthyl, anthracene, phenanthrene or pyrene group. The substituents can be, for example, an alkyl, aralkyl, alkoxy, aromatic, heterocyclic, polycyclic group, halogen such as fluorine, cyano, amino, substituted amino etc. Examples are given in FIGS. 1 and 2 of the drawings where R, R₁, R₂, R₃ and R₄ can be the same or different and are selected from hydrogen, hydrocarbyl groups, substituted and unsubstituted aromatic, heterocyclic and polycyclic ring structures, fluorocarbons such as trifluoryl methyl groups, halogens such as fluorine or thiophenyl groups; R, R₁, R₂, R₃ and R₄ can also form substituted and unsubstituted fused aromatic, heterocyclic and polycyclic ring structures and can be copolymerisable with a monomer, e.g. styrene. R, R₁, R₂, R₃ and R₄ can also be unsaturated alkylene groups such as vinyl groups or groups
—C—CH₂═CH₂—R
where R is as above.

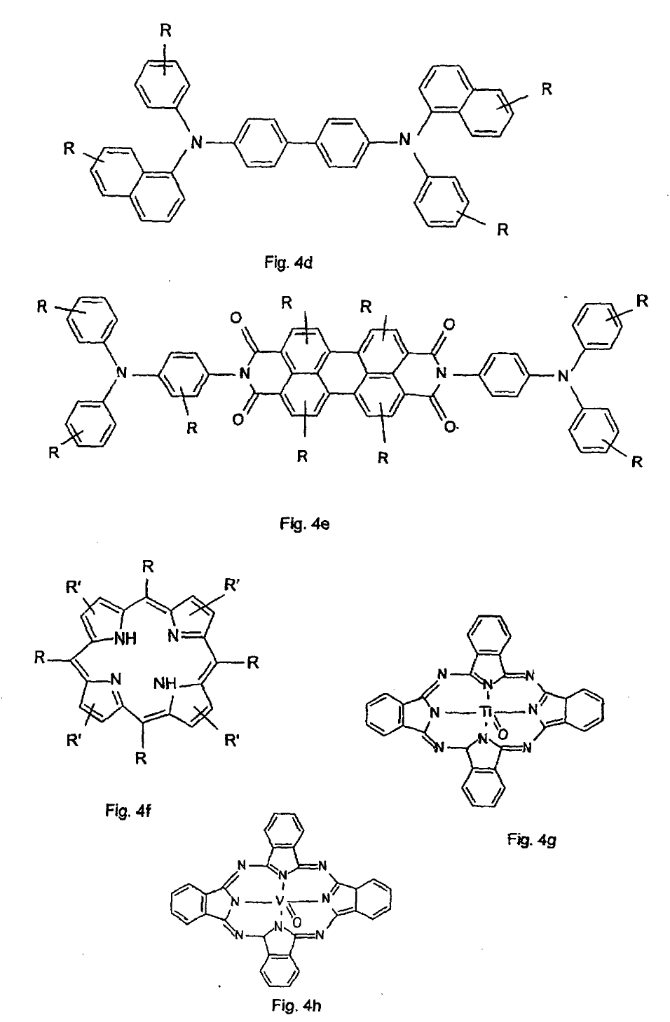

Lₚ can also be compounds of formulae 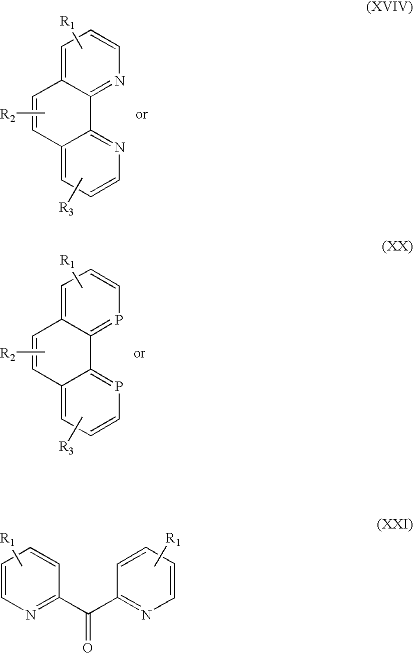
where R₁, R₂ and R₃ are as referred to above; for example bathophen shown in FIG. 3 of the drawings in which R is as above or 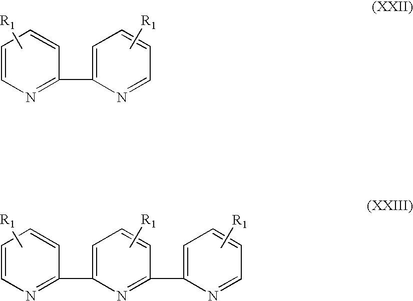
where R₁, R₂ and R₃ are as referred to above.

Lₚ can also be 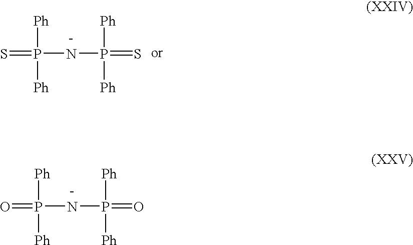
where Ph is as above.

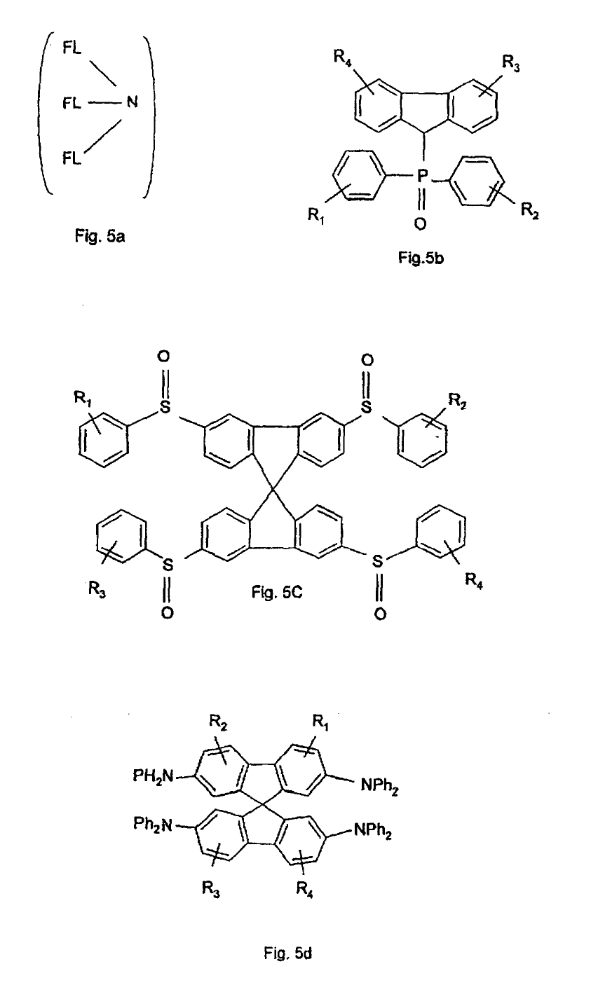

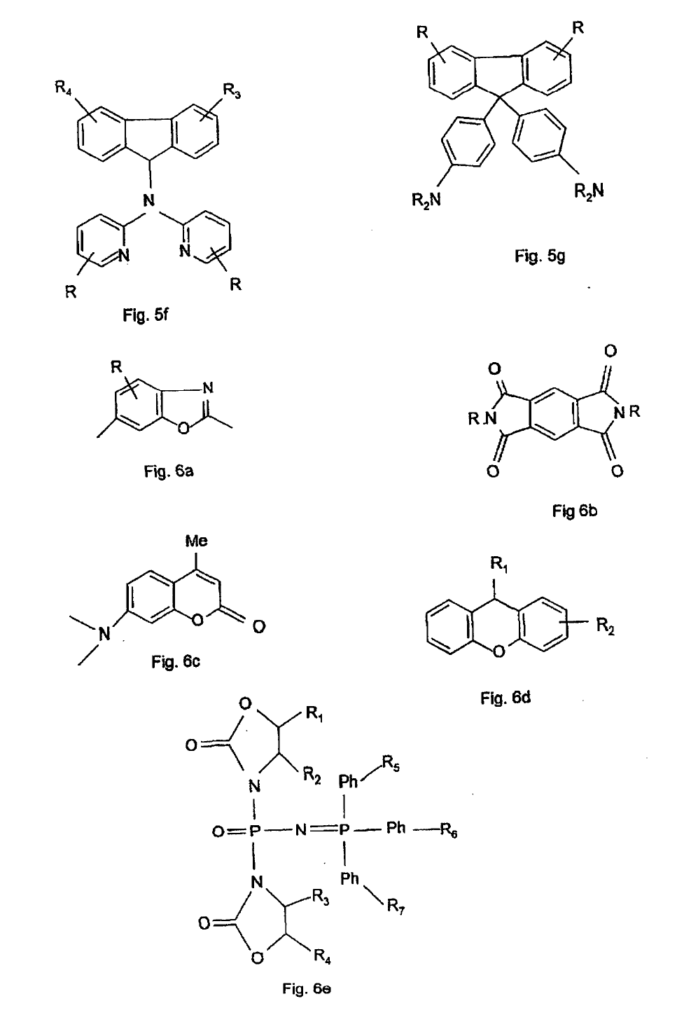

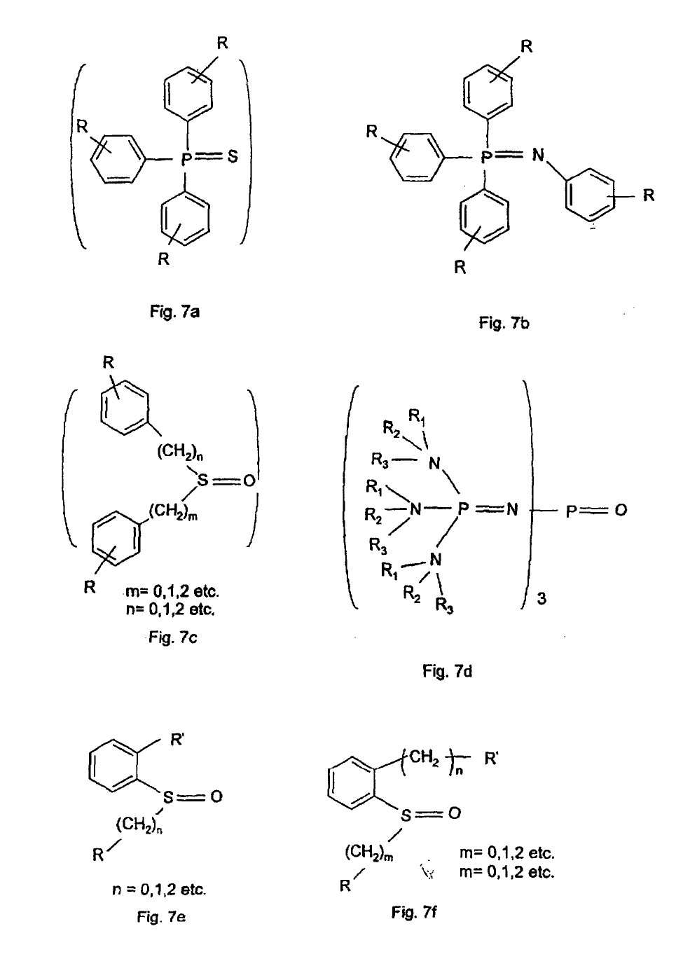

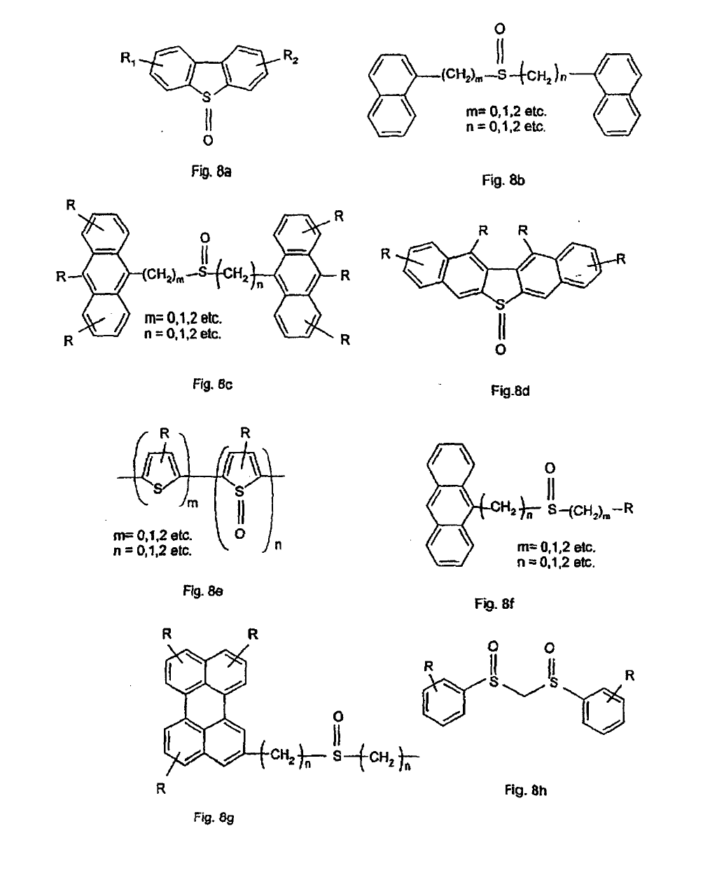

Other examples of Lₚ chelates are as shown in FIG. 4 and fluorene and fluorene derivatives, e.g. as shown in FIG. 5 and compounds of formulae as shown in FIGS. 6 to 8.

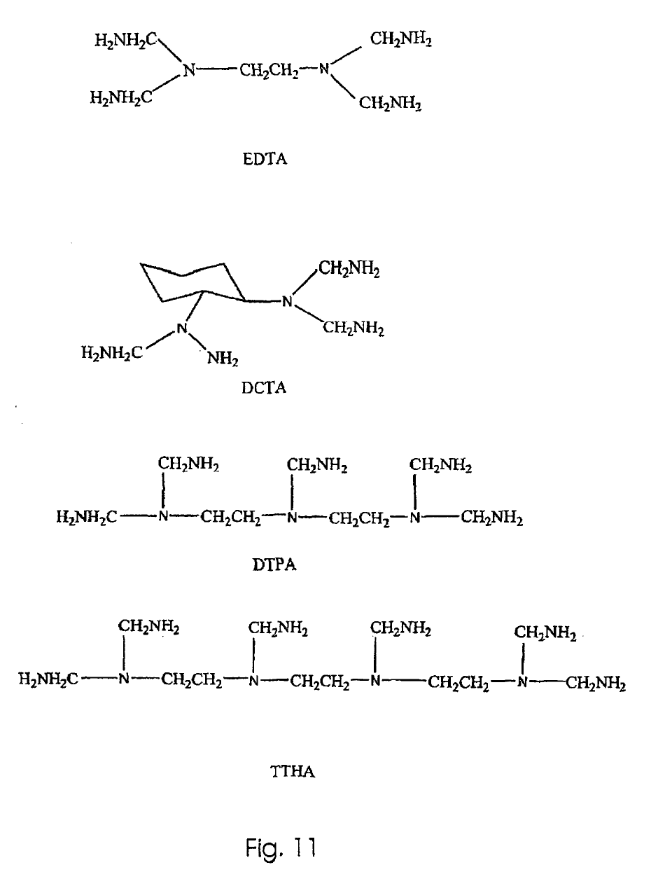

Specific examples of Lα and Lp are tripyridyl and TMHD, and TMHD complexes, α, α′, α″ tripyridyl, crown ethers, cyclans, cryptans phthalocyanans, porphoryins ethylene diamine tetramine (EDTA), DCTA, DTPA and TTHA. Where TMHD is 2,2,6,6-tetramethyl-3,5-heptanedionato and OPNP is diphenylphosphonimide triphenyl phosphorane. The formulae of the polyamines are shown in FIG. 11.

A preferred europium complex is Eu(DBM)₃OPNP.

In one embodiment of the invention there is provided a structure which comprises (i) a few electrode, (ii) a layer of a hole transporting, (iii) a layer of an electroluminescent europium organo metallic or organic complex mixed with an iridium organo metallic or organic complex (A), (iv) an electron transmitting layer and (v) a second electrode and preferably there is also one or more layers of a europium electroluminescent organo metallic or organic complex adjacent to the layer (iii).

Optionally there can be other layers such as buffer layers in order that the holes and electrons combine in the electroluminescent layer and to improve the overall performance of the device.

The invention is illustrated in the examples which exemplify the synthesis of the diiridium complex and a device incorporating it.

### EXAMPLE 1

### 3,4-diacetyl-2,5-hexanedione (I)

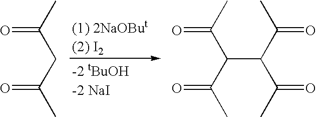

A three-necked 1 litre round-bottomed flask under an inert atmosphere (nitrogen) was charged with sodium tert-butoxide (30.0 g, 310 mmol) and a magnetic stirrer-bar. Thf (dried and distilled over Na/benzophenone, 500 mL) was introduced, the temperature reduced to −78° C. and pentane-2,4-dione (30.0 g, 300 mmol) in Thf (dried and distilled over Nalbenzophenone, 100 mL) added over 30 min. The reaction was allowed to warm to around 0° C. and cooled with an ice-bath to maintain the temperature below 5° C. Iodine (38.0 g, 150 mmol) in Thf (dried and distilled over Na/benzophenone, 100 mL) was added dropwise. The reaction mixture was stirred for a further 30 min. with the ice-bath and then for 1 hour once the ice-bath had been removed. Diethylether (300 mL) was added to the reaction mixture, which was then poured into 200 mL saturated ammonium chloride solution (the pH was measured to ensure that the product had been neutralised). The organic layer was washed with 0.25M sodium thiosulfate solution (2×200 mL) and then brine (200 mL). The volatiles were removed in vacuo and the product recrystallised from ethanol (95%) to yield colourless crystals (19.3 g, 65%). M.p. 193-4° C. The product was used without further purification.

### EXAMPLE 2

### Tetrakis(2-phenylpyridine-C², N′)(μ-chloro)diiridium (II)

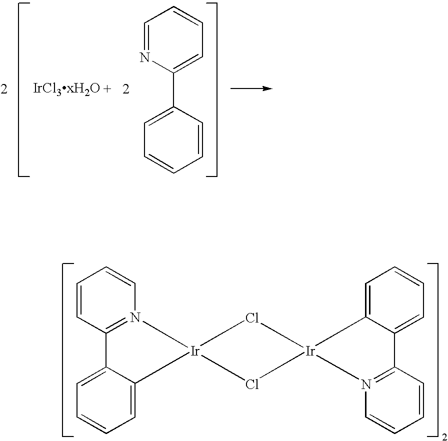

Iridium trichloride hydrate (0.388 g) was combined with 2-phenylpyridine (0.76 g), dissolved in a mixture of 2-ethoxyethanol (30 mL, dried and distilled over MgSO₄) and water (10 mL), and refluxed for 24 hours. The solution was cooled to room temperature and the yellow/green precipitate collected on a glass sinter. The precipitate was washed with ethanol (60 mL, 95%), acetone (60 mL), and then dissolved in dichloromethane (75 mL) and filtered. Toluene (25 mL) and hexane (10 mL) were added to the filtrate and the volume reduced in vacuo to about 50 mL. Cooling yielded crystals (yellow/green) of the desired product (0.43 g, 72%). This was used without further purification.

### EXAMPLE 3

### Tetrakis(2-phenylpyridine-C², N′)(μ-3,4-diacetyl-2,5-hexanedionate)diiridium

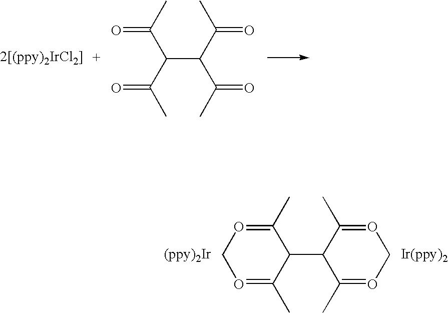

Tetrakis(2-phenylpyridine-C²,N′)(μ-chloro) diiridium (II) (0.5 g, 0.47 mmol), 3,4-diacetyl-2,5-hexanedione (I) (0.092 g, 0.47 mmol) and sodium carbonate (dried at 100° C., 200 mg, 1.9 mmol) were refluxed under an inert atmosphere (nitrogen) in 2-ethoxyethanol (dried and distilled over magnesium sulfate, 50 mL) for 12 hours. On cooling to room temperature, a yellow precipitate was collected on a sinter (porosity 3) and washed with water (50 mL), hexane (50 mL) and diethylether (50 mL). The crude product was flash chromatographed on a silica column using dichioromethane as eluent. The dichloromethane was reduced in volume to about 5 mL and then methanol (100 mL) was added. The solution was, once more, reduced in volume to about 50 mL and the yellow product filtered (sinter, porosity 3) and washed with further methanol (100 mL). The product was dried in a vacuum oven at 80° C. for 2 hours. Yield (030 g, 46%).

Device Construction

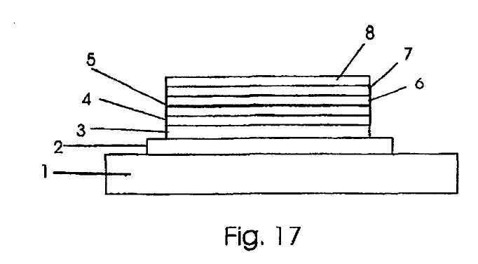

An electroluminescent device is shown in FIG. 17, where the layers 1 to 8 were (1) ITO, (2) CuPc (3) α-NPB (4) the electroluminescent mixture (5) BCP (6) Alq₃ (7) LiF and (8) Al. To form the device a pre-etched ITO coated glass piece (10×10 cm²) was used. The device was fabricated by sequentially forming the layers on the ITO, by vacuum evaporation using a Solciet Machine, ULVAC Ltd Chigacki, Japan; the active area of each pixel was 3 mm by 3 mm; the structure was:
ITO/CuPc(8 nm)α-NPB(40 nm)/CBP+Ir₂(diacac)₂(dpp)₂(12%)(20 nm)/BCP(6 mm)/Alq₃(20 nm)/LiF(0.7 mn)Al
where CBP is shown in FIG. 4b with R being H, BCP is bathocupron and Ir₂(diacac)₂ (dpp)₂ is as synthesised in example 3.

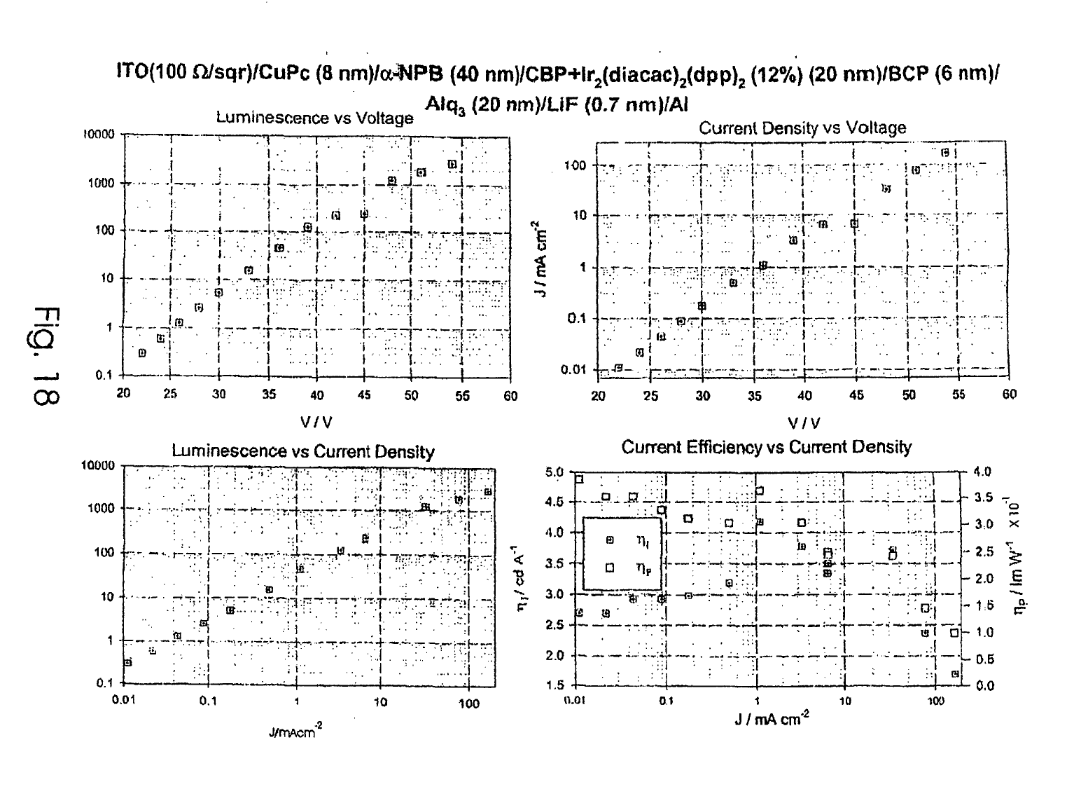

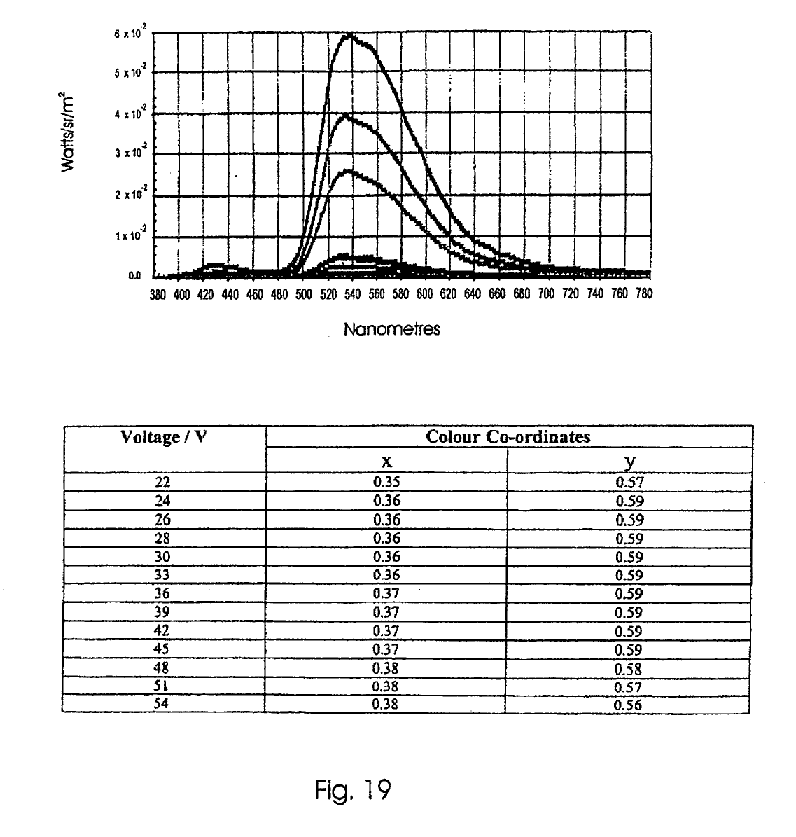

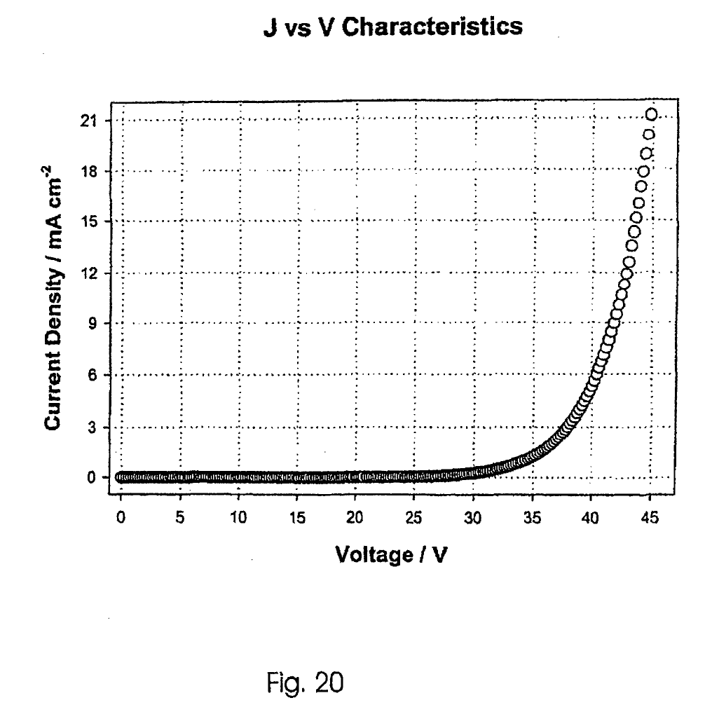

An electric current was passed through the device and the properties of the emitted light measured and the results are shown in FIGS. 18 to 20 of the drawings.

1.-32. (canceled)

33. An electroluminescent diiridium compound having the general chemical formula: 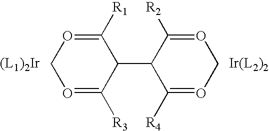
where R₁, R₂, R₃ and R₄ can be the same or different and are independently selected from hydrogen, and substituted and unsubstituted hydrocarbyl groups; and L₁ and L₂ are organic ligands.

34. A compound according to claim 33 where R₁, R₂, R₃ and R₄ are selected from substituted and unsubstituted aliphatic groups; substituted and unsubstituted aromatic, heterocyclic and polycyclic ring structures; fluorocarbon groups; and halogen groups; R₁, R₂ and R₃ can also form substituted and unsubstituted fused aromatic, heterocyclic and polycyclic ring structures and can be copolymerisable with a monomer; and L₁ and L₂ are the same or different organic ligands.

35. A diiridium compound according to claim 34 wherein L₁ and L₂ are selected from phenyl pyridine and substituted phenylpryidines.

36. An electroluminescent device comprising in combination: (i) a first electrode; (ii) a layer of a diiridium compound according to claim 33; and (iii) a second electrode.

37. An electroluminescent device comprising in combination: (i) a first electrode; (ii) a layer of a diiridium compound according to claim 34; and (iii) a second electrode.

38. An electroluminescent device according to claim 36 wherein the diiridium compound is mixed with an effective amount of an electroluminescent europium complex.

39. An electroluminescent device according to claim 38 wherein the europium complex is a europium organometallic or organic complex having the general chemical formula (Lα)₃Eu where Lα is an organic complex.

40. An electroluminescent device according to claim 38 wherein the europium organo metallic or organic complex has the general chemical formula
(Lα)₃Eu←Lp
where Lα and Lp are organic ligands with Lp being a neutral ligand, the ligands Lα can be the same or different, and there can also be a plurality of ligands Lp which can be the same or different.

41. An electroluminescent device according to claim 39 wherein the europium complex is Eu(DBM)₃OPNP.

42. An electroluminescent device according to claim 36 wherein there is a layer of a hole transmitting material positioned between the first electrode and the diiridium compound layer.

43. An electroluminescent device according to claim 37 wherein there is a layer of a hole transmitting material positioned between the first electrode and the diiridium compound layer.

44. An electroluminescent device according to claim 42 wherein the hole transmitting material is selected from aromatic amine complexes and conjugated polymers.

45. An electroluminescent device according to claim 42 wherein the hole transmitting material is a film of a polymer selected from poly(vinylcarbazole), N,N′-diphenyl-N,N′-bis(3-methylphenyl)-1,1′-biphenyl-4,4′-diamine (TPD), polyaniline, substituted polyanilines, polythiophenes, substituted polythiophenes, polysilanes and substituted polysilanes, a polymer of a cyclic aromatic compound, poly (p-phenylenevinylene)-PPV, copolymers of PPV, poly(2,5 dialkoxyphenylene vinylene), poly (2-methoxy-5-(2-methoxypentyloxy-1,4-phenylene vinylene), poly(2-methoxypentyloxy)-1,4-phenylenevinylene), poly(2-methoxy-5-(2-dodecyloxy-1,4-phenylenevinylene) and other poly(2,5 dialkoxyphenylenevinylenes) with at least one of the alkoxy groups being a long chain solubilising alkoxy group, poly fluorenes, oligofluorenes, polyphenylenes, oligophenylenes, polyanthracenes, oligo anthracenes, polythiophenes and oligothiophenes.

46. An electroluminescent device according to claim 36 wherein there is a layer of an electron transmitting material positioned between the diiridium compound layer and the second electrode.

47. An electroluminescent device according to claim 46 wherein the electron transmitting material is selected from metal quinolates and cyano anthracenes.

48. An electroluminescent device according to claim 46 wherein the electron transmitting material is an aluminium quinolate or lithium quinolate.

49. An electroluminescent device according to claim 46 wherein the second electrode is selected from aluminium, calcium, lithium, and silver/magnesium alloys.

50. An electroluminescent device according to claim 42 wherein the hole transmitting material and the diiridium compound are mixed to form one layer in a proportion ranging from about 5 to 95% of the hole transmitting material to about 95 to 5% of the diiridium compound.

51. An electroluminescent device according to claim 46 wherein the electron transmitting material and the diiridium compound are mixed to form one layer in a proportion ranging from about 5 to 95% of the electron transmitting material to about 95 to 5% of the diiridium compound.

52. An electroluminescent device according to claim 36 wherein there is a copper phthalocyanine layer on the first electrode and a lithium fluoride layer on the second electrode.

53. An electroluminescent device comprising in combination: (i) a first electrode; (ii) a layer of a hole transmitting material; (iii) a layer of a diiridium compound according to claim 33; (iv) a layer of an electron transmitting material; and (v) a second electrode.

54. An electroluminescent device according to claim 53 wherein the diiridium compound has the general chemical formula 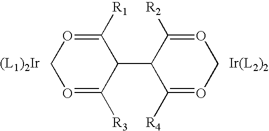
where R₁, R₂, R₃ and R₄ are independently selected from substituted and unsubstituted aliphatic groups; substituted and unsubstituted aromatic, heterocyclic and polycyclic ring structures; fluorocarbon groups; halogen or thiophenyl groups; R₁, R₂ and R₃ can also form substituted and unsubstituted fused aromatic, heterocyclic and polycyclic ring structures and can be copolymerisable with a monomer; and L₁ and L₂ are the same or different organic ligands.

55. An electroluminescent device according to claim 54 wherein L₁ and L₂ are selected from phenyl pyridine and substituted phenylpryidines.
